(19) United States
(12) Patent Application Publication
(10) Pub. No.: US 2024/0242932 A1
(43) Pub. Date: Jul. 18, 2024

(54) MULTI-CHARGED PARTICLE BEAM WRITING APPARATUS, AND MULTI-CHARGED PARTICLE BEAM WRITING METHOD

(71) Applicant: NuFlare Technology, Inc., Yokohama-shi (JP)

(72) Inventors: Yasuo KATO, Yokohama-shi (JP); Ryoh KAWANA, Yokohama-shi (JP); Masao HAYAMI, Yokohama-shi (JP)

(73) Assignee: NuFlare Technology, Inc., Yokohama-shi (JP)

(21) Appl. No.: 18/621,345

(22) Filed: Mar. 29, 2024

Related U.S. Application Data
(63) Continuation of application No. PCT/JP2022/027527, filed on Jul. 13, 2022.

(30) Foreign Application Priority Data
Oct. 7, 2021 (JP) 2021-165705

(51) Int. Cl. H01J 37/304; H01J 37/317

(52) U.S. Cl. CPC H01J 37/3045; H01J 37/3177; H01J 2237/24507

(57) ABSTRACT

A multi-charged particle beam writing apparatus includes a distribution ratio calculation circuit to calculate, for the each control grid and each combination of combinations, a dose distribution ratio for each beam of at least two beams forming a combination concerned in order to distribute a dose amount, which is to be applied to a control grid concerned, to the at least two beams forming the combination concerned such that a total of distribution dose amounts having been distributed to the at least two beams forming the combination concerned is substantially equivalent to the dose amount to be applied to the control grid concerned, and a combination selection circuit to select, for the each control grid, a combination in which a dose distribution ratio for the first beam is larger than a dose distribution ratio for at least one beam remaining in the at least two beams forming the combination concerned.

### CROSS-REFERENCE TO RELATED APPLICATION

This application is a continuation application based upon and claims the benefit of priority from prior Japanese Patent Application No. 2021-165705 (application number) filed on Oct. 7, 2021 in Japan, and International Application PCT/JP2022/027527, the International Filing Date of which is Jul. 13, 2022. The contents described in JP2021-165705 and PCT/JP2022/027527 are incorporated herein by reference.

### BACKGROUND OF THE INVENTION

### Field of the Invention

An embodiment of the present invention relates to a multi-charged particle beam writing apparatus and a multi-charged particle beam writing method, and for example, to a method for reducing pattern dimension deviation in multiple beam writing.

### Description of Related Art

The lithography technique which advances miniaturization of semiconductor devices is extremely important as a unique process whereby patterns are formed in semiconductor manufacturing. In recent years, with high integration of LSI, the line width (critical dimension) required for semiconductor device circuits is becoming increasingly finer year by year. The electron beam writing technique, which intrinsically has excellent resolution, is used for writing or “drawing” a mask pattern on a mask blank with electron beams.

For example, as a known example of employing the electron beam writing technique, there is a writing apparatus using multiple beams. Since it is possible for multi-beam (multiple beam) writing to apply multiple beams at a time, the writing throughput can be greatly increased in comparison with single electron beam writing. For example, a writing apparatus employing the multi-beam system forms multiple beams by letting an electron beam emitted from an electron gun pass through a mask having a plurality of holes, performs blanking control for each beam, reduces by an optical system each unblocked beam to reduce a mask image, and deflects a reduced beam by a deflector to irradiate a desired position on a target object or “sample”.

With respect to multiple beams, distortion occurs in an exposure field due to optical system characteristics, and therefore, the irradiation position of each beam deviates from an ideal grid because of the distortion and the like. For multiple beams, it is difficult to deflect each beam individually, thereby being difficult to individually control the position of each beam on the target object surface. Accordingly, the position deviation of each beam is corrected by dose modulation (e.g., refer to Japanese Patent Application Laid-open (JP-A) No. 2019-029575). However, when correcting a position deviation by dose modulation, there is a problem that the maximum modulation rate in dose modulation rates of respective beams after the dose modulation may become large. In connection with the maximum modulation rate becoming large, the maximum irradiation time becomes long.

### BRIEF SUMMARY OF THE INVENTION

According to one aspect of the present invention, a multi-charged particle beam writing apparatus includes
a beam forming mechanism configured to form multiple charged particle beams,
a specification circuit configured to specify, for each control grid of a plurality of control grids serving as beam design irradiation positions of the multiple charged particle beams, a first beam whose actual irradiation position is closest to a control grid of a beam concerned in the multiple charged particle beams,
a combination setting circuit configured to set, for the each control grid, a plurality of combinations each composed of at least two beams, including the first beam, in the multiple charged particle beams,
a distribution ratio calculation circuit configured to calculate, for the each control grid and each combination of the plurality of combinations, a dose distribution ratio for each beam of the at least two beams forming a combination concerned in order to distribute a dose amount, which is to be applied to a control grid concerned, to the at least two beams forming the combination concerned such that a total of distribution dose amounts having been distributed to the at least two beams forming the combination concerned is substantially equivalent to the dose amount to be applied to the control grid concerned,
a combination selection circuit configured to select, for the each control grid, a combination in which a dose distribution ratio for the first beam is larger than a dose distribution ratio for at least one beam remaining in the at least two beams forming the combination concerned,
a dose correction circuit configured to correct a dose amount of an irradiation position concerned by to which adding a dose amount having been distributed to each beam design irradiation position based on dose distribution ratios for the at least two beams forming the combination selected for the each control grid in a whole beam array of the multiple charged particle beams, and configured to output a corrected dose amount, and
a writing mechanism configured to write a pattern on a target object by using the multiple charged particle beams of the corrected dose amount.

According to another aspect of the present invention, a multi-charged particle beam writing method includes
forming multiple charged particle beams,
specifying, for each control grid of a plurality of control grids serving as beam design irradiation positions of the multiple charged particle beams, a first beam whose actual irradiation position is closest to a control grid of a beam concerned in the multiple charged particle beams,
setting, for the each control grid, a plurality of combinations each composed of at least two beams, including the first beam, in the multiple charged particle beams,
calculating, for the each control grid and each combination of the plurality of combinations, a dose distribution ratio for each beam of the at least two beams forming a combination concerned in order to distribute a dose amount, which is to be applied to a control grid concerned, to the at least two beams forming the combination concerned such that a total of distribution dose amounts having been distributed to the at least two beams forming the combination concerned is substantially equivalent to the dose amount to be applied to the control grid concerned,
selecting, for the each control grid, a combination in which a dose distribution ratio for the first beam is larger than a dose distribution ratio for at least one beam remaining in the at least two beams forming the combination concerned,
correcting a dose amount of an irradiation position concerned by to which adding a dose amount having been distributed to each beam design irradiation position based on dose distribution ratios for the at least two beams forming the combination selected for the each control grid in a whole beam array of the multiple charged particle beams, and outputting a corrected dose amount, and
writing a pattern on a target object by using the multiple charged particle beams of the corrected dose amount.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram illustrating an example of a writing operation according to the first embodiment;

FIG. 5 is an illustration showing an example of an irradiation region of multiple beams and a pixel to be written according to the first embodiment;

FIG. 6 is an illustration showing an example of a writing method of multiple beams according to the first embodiment;

FIG. 7 is a flowchart showing main steps of a writing method according to the first embodiment;

FIG. 8A is an illustration showing a beam position deviation and a position deviation periodicity according to the first embodiment;

FIG. 8B is an illustration showing a beam position deviation and a position deviation periodicity according to the first embodiment;

FIG. 9 is an illustration showing an example of a beam irradiation position and a dose distribution ratio in the case of correcting a position deviation according to a comparative example of the first embodiment;

FIG. 10 is an illustration showing another example of a beam irradiation position and a dose distribution ratio in the case of correcting a position deviation according to a comparative example of the first embodiment;

FIG. 11 is an illustration showing an example of a control grid and an actual beam irradiation position according to the first embodiment;

FIG. 12 is an illustration showing an example of a restricted region according to the first embodiment;

FIG. 13 is an illustration showing an example of a control grid, an actual beam irradiation position, and a combination of beams according to the first embodiment;

FIG. 14 is an illustration showing an example of a current density distribution according to the first embodiment;

FIG. 15 is an illustration showing an example of a result of simulation on a relationship between the maximum modulation rate and the maximum positional deviation amount associated with positional deviation correction according to the first embodiment; and

FIG. 16 is a block diagram showing an example of the internal configuration of a repetitive operation processing unit according to the first embodiment.

### DETAILED DESCRIPTION OF THE INVENTION

Embodiments below provide an apparatus and method that can, in multiple beam writing, suppress an increase in a dose modulation rate when correcting a position deviation of each beam by dose modulation.

Embodiments below describe a configuration in which an electron beam is used as an example of a charged particle beam. The charged particle beam is not limited to the electron beam, and other charged particle beam such as an ion beam may also be used.

### First Embodiment

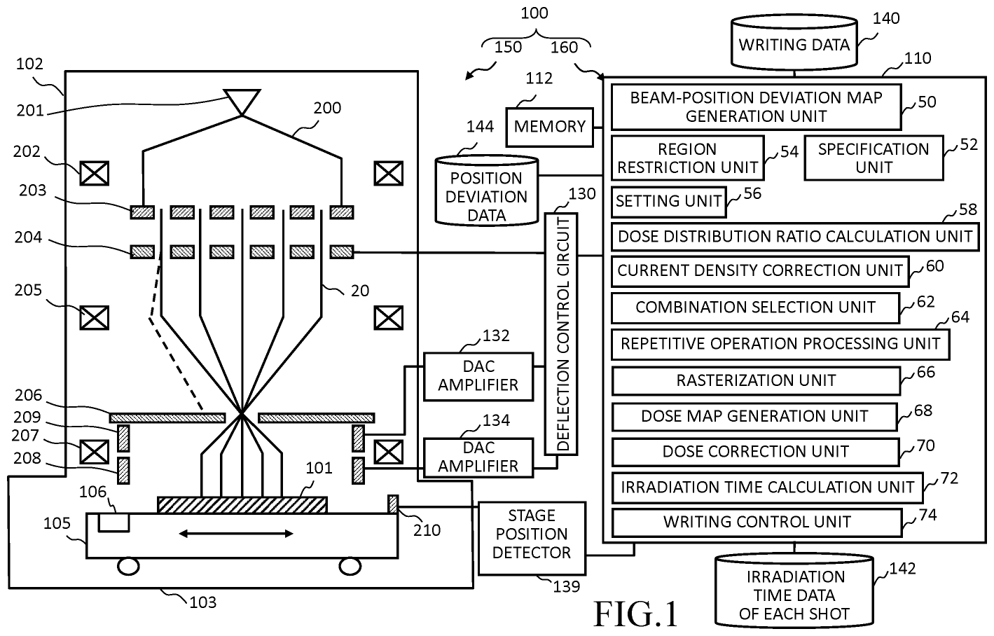

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multi-charged particle beam writing apparatus. The writing mechanism 150 includes an electron beam column 102 (multi-electron beam column) and a writing chamber 103. In the electron beam column 102, there are disposed an electron gun 201, an illumination lens 202, a shaping aperture array substrate 203, a blanking aperture array mechanism 204, a reducing lens 205, a limiting aperture substrate 206, an objective lens 207, a deflector 208, and a deflector 209. In the writing chamber 103, an XY stage 105 is disposed. On the XY stage 105, there is placed a target object or “sample” 101 such as a mask blank, on which resist has been applied, serving as a writing target substrate when writing is performed. The target object 101 is, for example, an exposure mask used when fabricating semiconductor devices, or a semiconductor substrate (silicon wafer) for fabricating semiconductor devices. Further, on the XY stage 105, a mirror 210 for measuring the position of the XY stage 105 is placed. Furthermore, a Faraday cup 106 is placed on the XY stage 105.

The control system circuit 160 includes a control computer 110, a memory 112, a deflection control circuit 130, DAC (digital-analog converter) amplifier units 132 and 134, a stage position detector 139, and storage devices 140, 142, and 144 such as magnetic disk drives. The control computer 110, the memory 112, the deflection control circuit 130, the DAC amplifier units 132 and 134, the stage position detector 139, and the storage devices 140, 142, and 144 are connected to each other through a bus (not shown). The DAC amplifier units 132 and 134 and the blanking aperture array mechanism 204 are connected to the deflection control circuit 130. Outputs of the DAC amplifier unit 132 are connected to the deflector 209. Outputs of the DAC amplifier unit 134 are connected to the deflector 208. The deflector 208 is composed of at least four electrodes (or “poles”), and controlled by the deflection control circuit 130 through a corresponding amplifier, disposed for each electrode, of the DAC amplifier unit 134. The deflector 209 is composed of at least four electrodes (or “poles”), and controlled by the deflection control circuit 130 through a corresponding amplifier, disposed for each electrode, of the DAC amplifier unit 132. The stage position detector 139 emits a laser light to the mirror 210 on the XY stage 105, and receives a reflected light from the mirror 210. The stage position detector 139 measures the position of the XY stage 105, based on the principle of laser interferometry which uses information of the reflected light.

In the control computer 110, there are arranged a beam-position deviation map generation unit 50, a specification unit 52, a region restriction unit 54, a setting unit 56, a dose distribution ratio calculation unit 58, a current density correction unit 60, a combination selection unit 62, a repetitive operation processing unit 64, a rasterization unit 66, a dose map generation unit 68, a dose correction unit 70, an irradiation time calculation unit 72, and a writing control unit 74. Each of the “ . . . units” such as the beam-position deviation map generation unit 50, the specification unit 52, the region restriction unit 54, the setting unit 56, the dose distribution ratio calculation unit 58, the current density correction unit 60, the combination selection unit 62, the repetitive operation processing unit 64, the rasterization unit 66, the dose map generation unit 68, the dose correction unit 70, the irradiation time calculation unit 72, and the writing control unit 74 includes processing circuitry. The processing circuitry includes, for example, an electric circuit, computer, processor, circuit board, quantum circuit, or semiconductor device. Each “ . . . unit” may use common processing circuitry (the same processing circuitry), or different processing circuitry (separate processing circuitry). Information input/output to/from the beam-position deviation map generation unit 50, the specification unit 52, the region restriction unit 54, the setting unit 56, the dose distribution ratio calculation unit 58, the current density correction unit 60, the combination selection unit 62, the repetitive operation processing unit 64, the rasterization unit 66, the dose map generation unit 68, the dose correction unit 70, the irradiation time calculation unit 72, and the writing control unit 74, and information being operated are stored in the memory 112 each time.

Writing data is input from the outside of the writing apparatus 100, and stored in the storage device 140. The writing data generally defines information on a plurality of figure patterns to be written. Specifically, it defines a figure code, coordinates, size, etc. of each figure pattern.

FIG. 1 shows a configuration necessary for describing the first embodiment. Other configuration elements generally necessary for the writing apparatus 100 may also be included therein.

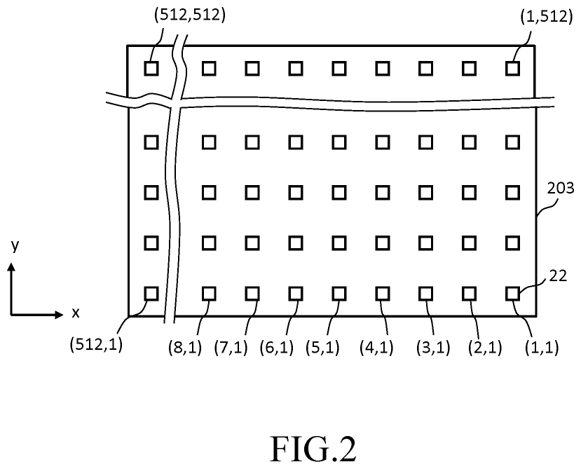

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≤2) are formed, like a matrix, at a predetermined arrangement pitch in the shaping aperture array substrate 203. In the case of FIG. 2, for example, holes 22 of 512×512, that is 512 (rows of holes arrayed in the y direction)×512 (columns of holes arrayed in the x direction), are formed. Each of the holes 22 is rectangular, including square, having the same dimension and shape as each other. Alternatively, each of the holes 22 may be a circle with the same diameter as each other. The shaping aperture array substrate 203 (beam forming mechanism) forms the multiple beams 20. Specifically, the multiple beams 20 are formed by letting portions of an electron beam 200 individually pass through a corresponding one of a plurality of holes 22. The method of arranging the holes 22 is not limited to the case of FIG. 2 where the holes are arranged like a grid in the width and length directions. For example, with respect to the x-direction kth and (k+1) th rows which are arrayed in the length direction (in the y direction), each hole in the kth row and each hole in the (k+1) th row may be arranged mutually displaced in the width direction (in the x direction) by a dimension “a”. Similarly, with respect to the x-direction (k+1) th and (k+2) th rows which are arrayed in the length direction (in the y direction), each hole in the (k+1) th row and each hole in the (k+2) th row may be arranged mutually displaced in the width direction (in the x direction) by a dimension “b”.

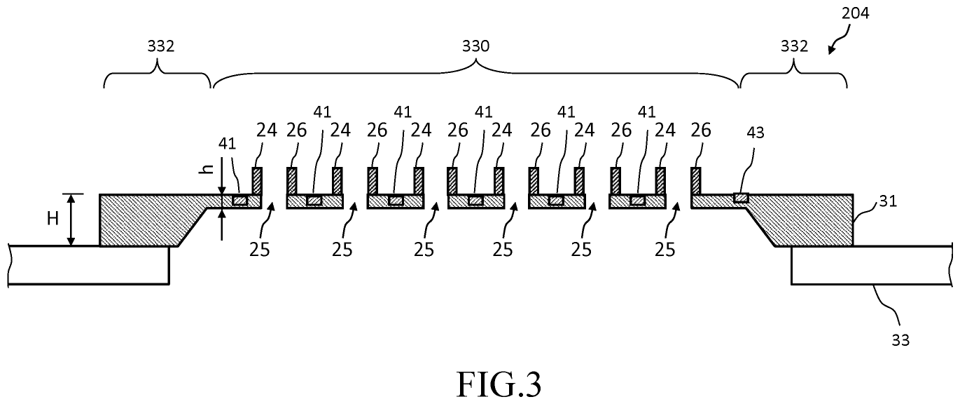

FIG. 3 is a sectional view showing a configuration of a blanking aperture array mechanism according to the first embodiment. With regard to the structure of the blanking aperture array mechanism 204, as shown in FIG. 3, a semiconductor substrate 31 made of silicon, etc. is placed on a support table 33. The central part of the substrate 31 is shaved, for example, from the back side and processed into a membrane region 330 (the first region) having a thin film thickness h. The periphery surrounding the membrane region 330 is an outer peripheral region 332 (the second region) having a thick film thickness H. The upper surface of the membrane region 330 and that of the outer peripheral region 332 are formed to be flush or substantially flush in height with each other. At the back side of the outer peripheral region 332, the substrate 31 is supported on the support table 33. The central part of the support table 33 is open, and the membrane region 330 is located at this opening region.

In the membrane region 330, passage holes 25 (openings) through each of which a corresponding one of the multiple beams 20 passes are formed at positions each corresponding to each hole 22 in the shaping aperture array substrate 203 shown in FIG. 2. In other words, in the membrane region 330 of the substrate 31, there are formed a plurality of passage holes 25, in an array state, through each of which a corresponding one of the multiple electron beams 20 passes. Further, in the membrane region 330 of the substrate 31, there are arranged a plurality of electrode pairs each composed of two electrodes being opposite to each other across a corresponding one of a plurality of passage holes 25. Specifically, in the membrane region 330, as shown in FIG. 3, each pair of a control electrode 24 and a counter electrode 26, (blanker: blanking deflector), for blanking deflection is arranged close to a corresponding passage hole 25 in a manner such that the electrodes 24 and 26 are opposite to each other across the passage hole 25 concerned. Further, close to each passage hole 25 in the membrane region 330, inside the substrate 31, there is arranged a control circuit 41 (logic circuit) which applies a deflection voltage to the control electrode 24 for the passage hole 25 concerned. The counter electrode 26 for each beam is grounded.

In the control circuit 41, an amplifier (not shown) (an example of a switching circuit) is arranged. As an example of the amplifier, a CMOS (complementary MOS) inverter circuit is arranged. The CMOS inverter circuit is connected to a positive potential (Vdd: blanking potential: first potential) (e.g., 5 V) (the first potential) and to a ground potential (GND: the second potential). The output line (OUT) of the CMOS inverter circuit is connected to the control electrode 24. By contrast, the counter electrode 26 is applied with a ground potential. A plurality of control electrodes 24, each of which is applied with a blanking potential and a ground potential in a switchable manner, are arranged on the substrate 31 such that each control electrode 24 and the corresponding counter electrode 26 are opposite to each other across the passage hole 25 concerned in the plurality of passage holes 25.

As an input (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit becomes a positive potential (Vdd), and then, a corresponding one of the multiple beams 20 is deflected by an electric field due to a potential difference from the ground potential of the counter electrode 26, and controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding one of the multiple beams 20 is not deflected, and controlled to be in a beam ON condition by passing through the limiting aperture substrate 206.

A corresponding one of the multiple beams 20, passing through a corresponding passage hole, is deflected by a voltage independently applied to a pair of the control electrode 24 and the counter electrode 26. Blanking control is provided by this deflection. Specifically, a pair of the control electrode 24 and the counter electrode 26 individually provides blanking deflection of a corresponding beam of the multiple beams 20 by an electric potential switchable by the CMOS inverter circuit serving as a switching circuit corresponding to each pair. Thus, each of a plurality of blankers performs blanking deflection of a corresponding one of the multiple beams 20 having passed through a plurality of holes 22 (openings) in the shaping aperture array substrate 203.

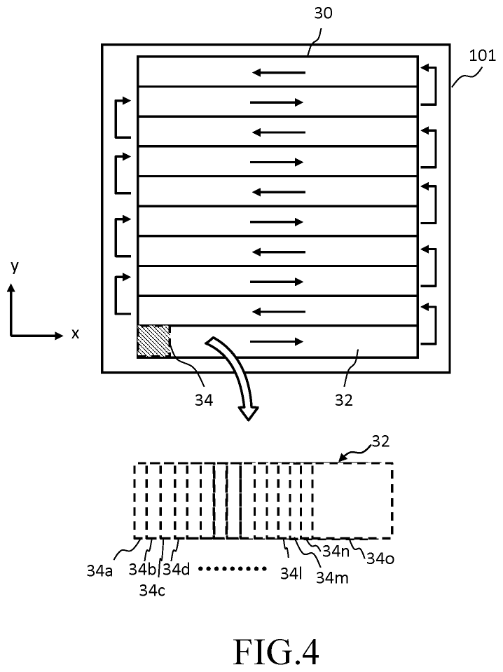

FIG. 4 is a conceptual diagram illustrating an example of a writing operation according to the first embodiment. As shown in FIG. 4, a writing region 30 of the target object 101 is virtually divided, for example, by a predetermined width in the y direction into a plurality of stripe regions 32 in a strip form. First, the XY stage 105 is moved to make an adjustment such that an irradiation region 34 which can be irradiated with one shot of the multiple beams 20 is located at the left end of the first stripe region 32 or at a position further left than the left end, and then writing is started. When writing the first stripe region 32, the writing is relatively proceeds in the x direction by moving the XY stage 105 in the −x direction, for example. The XY stage 105 is moved, for example, continuously at a constant speed. After writing the first stripe region 32, the stage position is moved in the −y direction to make an adjustment such that the irradiation region 34 is located at the right end of the second stripe region 32 or at a position further right than the right end to be thus located relatively in the y direction. Then, by moving the XY stage 105 in the x direction, for example, writing proceeds in the −x direction. That is, writing is performed while alternately changing the direction, such as performing writing in the x direction in the third stripe region 32, and in the −x direction in the fourth stripe region 32, thereby reducing the writing time. However, the writing operation is not limited to the writing while alternately changing the direction, and it is also preferable to perform writing in the same direction when writing each stripe region 32. A plurality of shot patterns maximally up to as many as the number of a plurality of holes 22 in the shaping aperture array substrate 203 are formed at a time by one shot of multiple beams having been formed by passing through the holes 22 in the shaping aperture array substrate 203. Further, although FIG. 4 shows the case where writing is performed once for each stripe region 32, it is not limited thereto. It is also preferable to perform multiple writing which writes the same region multiple times. In performing the multiple writing, preferably, the stripe region 32 of each pass is set while shifting the position.

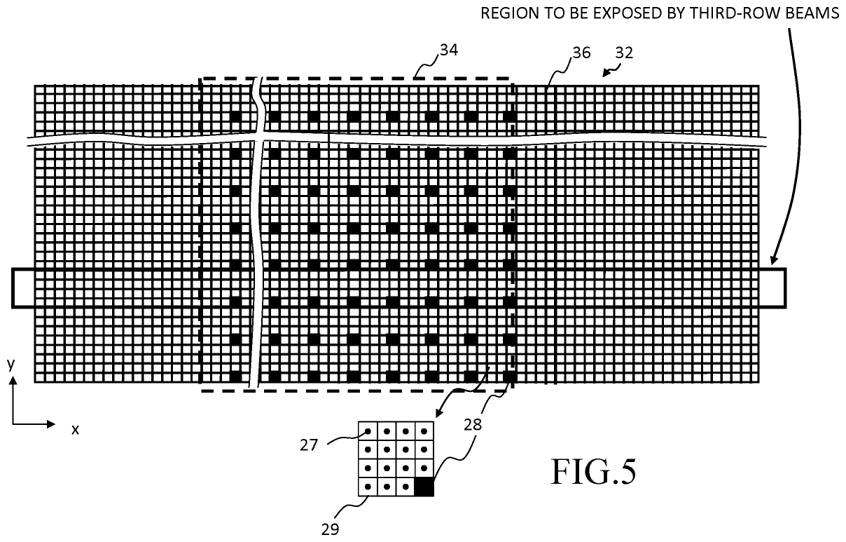

FIG. 5 is an illustration showing an example of an irradiation region of multiple beams and a pixel to be written (writing target pixel) according to the first embodiment. In FIG. 5, in the stripe region 32, there are set a plurality of control grids 27 (design grids) arranged in a grid form at the beam size pitch of the multiple beams 20 on the surface of the target object 101, for example.

Preferably, the control grids 27 are arranged at a pitch of around 10 nm. The plurality of control grids 27 serve as design irradiation positions (irradiation positions in design) of the multiple beams 20. The arrangement pitch of the control grid 27 is not limited to the beam size, and may be any size that can be controlled as a deflection position of the deflector 209, regardless of the beam size. Then, a plurality of pixels 36 are set by virtually dividing into meshes, each centering on each control grid 27, by the same size as that of the arrangement pitch of the control grid 27. Each pixel 36 serves as an irradiation unit region per beam of the multiple beams. FIG. 5 shows the case where the writing region of the target object 101 is divided, for example, in the y direction, into a plurality of stripe regions 32 by the width size being substantially the same as the size of the irradiation region 34 (writing field) which can be irradiated by one irradiation with the multiple beams 20 (beam array). The x-direction size of the irradiation region 34 can be defined by the value obtained by multiplying the x-direction beam pitch (pitch between beams) of the multiple beams 20 by the number of x-direction beams. The y-direction size of the irradiation region 34 can be defined by the value obtained by multiplying the y-direction beam pitch of the multiple beams 20 by the number of y-direction beams. The width of the stripe region 32 is not limited to this. Preferably, the width of the stripe region 32 is n times (n being an integer of one or more) the size of the irradiation region 34. FIG. 5 shows the case where the multiple beams of 512×512 (rows×columns) are simplified to 8×8 (rows×columns). In the irradiation region 34, there are shown a plurality of pixels 28 (beam writing positions) which can be irradiated with one shot of the multiple beams 20. In other words, the pitch between adjacent pixels 28 is the pitch between beams of the design multiple beams. In the example of FIG. 5, one sub-irradiation region 29 is a region surrounded by beam pitches. In the case of FIG. 5, each sub-irradiation region 29 is composed of 4×4 pixels.

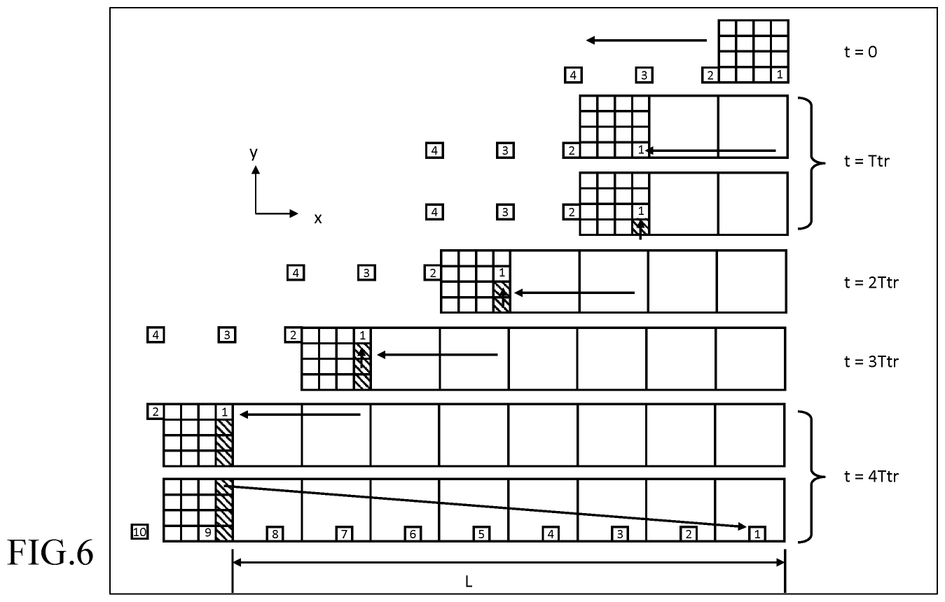

FIG. 6 is an illustration showing an example of a writing method of multiple beams according to the first embodiment. FIG. 6 shows a portion of the sub-irradiation region 29 to be written by each of beams at the coordinates (1, 3), (2, 3), (3, 3), . . . , (512, 3) of the y-direction k-th row in the multiple beams for writing the stripe region 32 shown in FIG. 5. In the example of FIG. 6, while the XY stage 105 moves the distance of eight beam pitches, four pixels are written (exposed), for example. In order that the relative position between the irradiation region 34 and the target object 101 may not deviate by the movement of the XY stage 105 while these four pixels are written (exposed), all of the multiple beams 20 are collectively deflected by the deflector 208. Thereby, the irradiation region 34 is made to follow the movement of the XY stage 105. In other words, tracking control is performed. In the case of FIG. 6, one tracking cycle is executed by writing (exposing) four pixels during moving the distance of eight beam pitches.

Specifically, in each shot, beam irradiation is performed during an irradiation time (writing time or exposure time) corresponding to each control grid 27 within the set-up maximum irradiation time. Specifically, each control grid 27 is irradiated with a corresponding ON beam in the multiple beams 20. Then, at each completion of the shot cycle time Ttr obtained by adding a settling time of the DAC amplifier to the maximum irradiation time, the irradiation position of each beam is moved to the next shot position by a collective deflection by the deflector 209.

In the case of FIG. 6, when four shots have been completed, the DAC amplifier unit 134 resets a beam deflection for tracking control. Thereby, the tracking position is returned to the start position of tracking where the tracking control was started.

Writing of the pixels in the first column from the right of each sub-irradiation region 29 has been completed. Therefore, after resetting the tracking, in a next tracking cycle, the deflector 209 first performs deflection to adjust (shift) the irradiation position of each corresponding beam to the control grid 27 of the pixel in the bottom row and the second column from the right of each sub-irradiation region 29. By repeating such an operation, all the pixels are written. When the sub-irradiation region 29 is composed of n×n pixels, each n pixels are written by different beams by n-time tracking operations. Thereby, all of the pixels in one region of n×n pixels are written. With respect also to other regions each composed of n×n pixels in the irradiation region of the multiple beams, the same operation is executed at the same time so as to perform writing similarly.

Next, operations of the writing mechanism 150 of the writing apparatus 100 will be described. The electron beam 200 emitted from the electron gun 201 (emission source) illuminates the whole of the shaping aperture array substrate 203 by the illumination lens 202. A plurality of rectangular (including square) holes 22 (openings) have been formed in the shaping aperture array substrate 203. Then, the region including all of the plurality of holes 22 is irradiated with the electron beam 200. Portions of the electron beam 200 applied to the positions of the plurality of holes 22 individually pass through a corresponding hole of the plurality of holes 22 of the shaping aperture array substrate 203. Thereby, for example, a plurality of rectangular (including square) electron beams (multiple beams 20) are formed. The multiple beams 20 individually pass through corresponding blankers (the first deflector: individual blanking mechanism) of the blanking aperture array mechanism 204. Each blanker deflects (provides blanking deflection) the electron beam passing therethrough individually.

The multiple beams 20 having passed through the blanking aperture array mechanism 204 are reduced by the reducing lens 205, and travel toward the hole in the center of the limiting aperture substrate 206. Then, an electron beam in the multiple beams 20 which was deflected by the blanker of the blanking aperture array mechanism 204 deviates (shifts) from the hole in the center of the limiting aperture substrate 206 and is blocked by the limiting aperture substrate 206. In contrast, an electron beam which was not deflected by the blanker of the blanking aperture array mechanism 204 passes through the hole in the center of the limiting aperture substrate 206 as shown in FIG. 1. Blanking control is provided by ON/OFF of an individual blanking mechanism 47 so as to control ON/OFF of beams. Thus, the limiting aperture substrate 206 blocks each beam which was deflected to be in the OFF state by the individual blanking mechanism 47. Then, for each beam, one shot beam is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, respective beams having passed through the limiting aperture substrate 206 (the whole of the multiple beams 20 having passed) are collectively deflected in the same direction by the deflectors 208 and 209 in order to irradiate respective beam irradiation positions on the target object 101. Ideally, the multiple beams 20 irradiating at a time are aligned at the pitch obtained by multiplying the arrangement pitch of the plurality of holes 22 of the shaping aperture array substrate 203 by a desired reduction ratio described above.

As described above, in multiple beam writing, distortion occurs in an exposure field due to optical system characteristics, and therefore, the irradiation position of each beam of the multiple beams 20 deviates from an ideal grid because of the distortion and the like. It is difficult to individually deflect each beam of the multiple beams 20, thereby being difficult to individually control the position of each beam on the target object surface. Accordingly, the position deviation of each beam is corrected by dose modulation. However, the maximum modulation rate in dose modulation rates of respective beams after the dose modulation may become large. In connection with the maximum modulation rate becoming large, the maximum irradiation time becomes long. Then, according to the first embodiment, attention is paid to the most proximate beam that irradiates the control grid 27 most closely, and the maximum modulation rate is reduced by increasing the dose distribution amount to the most proximate beam. It is specifically described below.

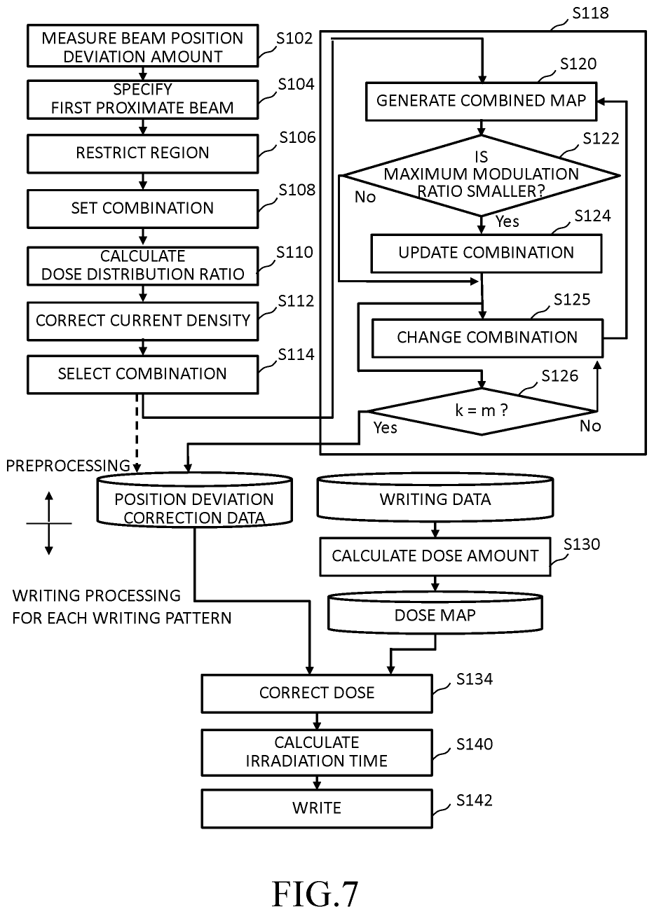

FIG. 7 is a flowchart showing main steps of a writing method according to the first embodiment. In FIG. 7, the writing method of the first embodiment executes a series of steps: a beam position deviation amount measuring step (S102), a first proximate beam specifying step (S104), a region restricting step (S106), a combination setting step (S108), a dose distribution ratio calculating step (S110), a current density correcting step (S112), a combination selecting step (S114), a repetitive operation processing step (S118), a dose amount calculating step (S130), a dose correcting step (S134), an irradiation time calculating step (S140), and a writing step (S142).

Each of the following steps are executed as preprocessing before starting writing processing: the beam position deviation amount measuring step (S102), the first proximate beam specifying step (S104), the region restricting step (S106), the combination setting step (S108), the dose distribution ratio calculating step (S110), the current density correcting step (S112), the combination selecting step (S114), and the repetitive operation processing step (S118).

Although, in the writing method of the first embodiment, the repetitive operation processing step (S118) is preferably executed, it may be omitted. When omitting the repetitive operation processing step (S118), the repetitive operation processing unit 64 arranged in the control computer 110 in FIG. 1 may be omitted. When executing the repetitive operation processing step (S118), a series of steps are performed as its internal steps: a combined map generating step (S120), a determining step (S122), a combination updating step (S124), a combination changing step (S125), and a determining step (S126).

Further, although, in the writing method of the first embodiment, the current density correcting step (S112) is preferably executed, it may be omitted. When omitting the current density correcting step (S112), the current density correction unit 60 arranged in the control computer 110 in FIG. 1 may be omitted.

In the beam position deviation amount measuring step (S102), the writing apparatus 100 measures the amount of position deviation of the irradiation position of each beam of the multiple beams 20, on the surface of the target object 101, deviated from a corresponding control grid 27.

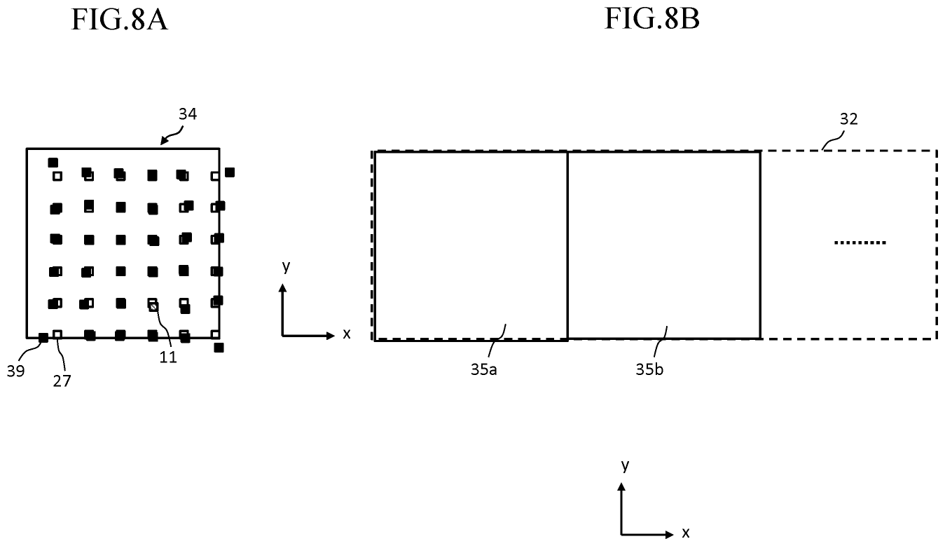

FIGS. 8A and 8B are illustrations each showing a beam position deviation and a position deviation periodicity according to the first embodiment. In the multiple beams 20, as shown in FIG. 8A, distortion occurs in an exposure field due to optical system characteristics, and therefore, an actual irradiation position 39 of each beam is deviated from the control grid 27 being an ideal grid because of the distortion and the like. Then, according to the first embodiment, the amount of position deviation of the actual irradiation position 39 of each beam is measured.

Specifically, an evaluation substrate coated with resist is irradiated with the multiple beams 20, and is developed in order to generate a resist pattern. Then, the position of the generated resist pattern is measured by a position measuring instrument, thereby measuring a position deviation amount of each beam. If it is difficult to measure the size of the resist pattern at the irradiation position of each beam by a position measuring instrument since the shot size of the beam concerned is small, a figure pattern (e.g., rectangular pattern) of a measurable size by a position measuring instrument is to be written. Then, edge positions of the both sides of the figure pattern (resist pattern) are measured to measure a position deviation amount of a target beam based on a difference between the intermediate position of the both edges and the intermediate position of a design figure pattern (figure pattern in design). Obtained position deviation amount data on each beam irradiation position is input to the writing apparatus 100, and stored in the storage device 144. In the multiple beam writing, since writing proceeds while shifting the irradiation region 34 in the stripe region 32, the position of the irradiation region 34 moves one by one, such as from the irradiation region 34a to 340, during writing of the stripe region 32 as shown in the lower part of FIG. 4 in the case of the writing sequence explained in FIG. 6, for example. Then, periodicity occurs in position deviation of each beam every time the irradiation region 34 is moved. Alternatively, if in the case of the writing sequence where each beam irradiates all of the pixels 36 in the sub-irradiation region 29 corresponding to the beam concerned, as shown in FIG. 8B, periodicity occurs in the position deviation of each beam at least in each unit region 35 (35a, 35b, . . . ) of the same size as the irradiation region 34. Therefore, when the position deviation amount of each beam for one irradiation region 34 is measured, the measurement result can also be used for other regions. In other words, it is sufficient to measure a position deviation amount at each pixel 36 in the sub-irradiation region 29 corresponding to each beam.

The beam-position deviation map generation unit 50 generates a beam-position deviation amount map which defines a position deviation amount of the beam of each pixel 36 in a beam array unit, in other words, one quadrangular unit region 35 on the surface of the target object corresponding to the irradiation region 34. Specifically, the beam-position deviation map generation unit 50 reads position deviation amount data on the irradiation position of each beam from the storage device 144, and generates a beam-position deviation amount map by using the data as a map value. Which beam irradiates the control grid 27 of each pixel 36 in one quadrangular unit region 35 on the surface corresponding to the irradiation region 34 of the whole of the multiple beams 20 is determined based on the writing sequence as described with reference to FIG. 6, for example. Therefore, the beam-position deviation map generation unit 50 specifies, per control grid 27 of each pixel 36 in one unit region 35, a beam to irradiate the control grid 27 concerned according to the writing sequence, and calculates a position deviation amount of the beam concerned. The generated beam-position deviation amount map is stored in the storage device 144.

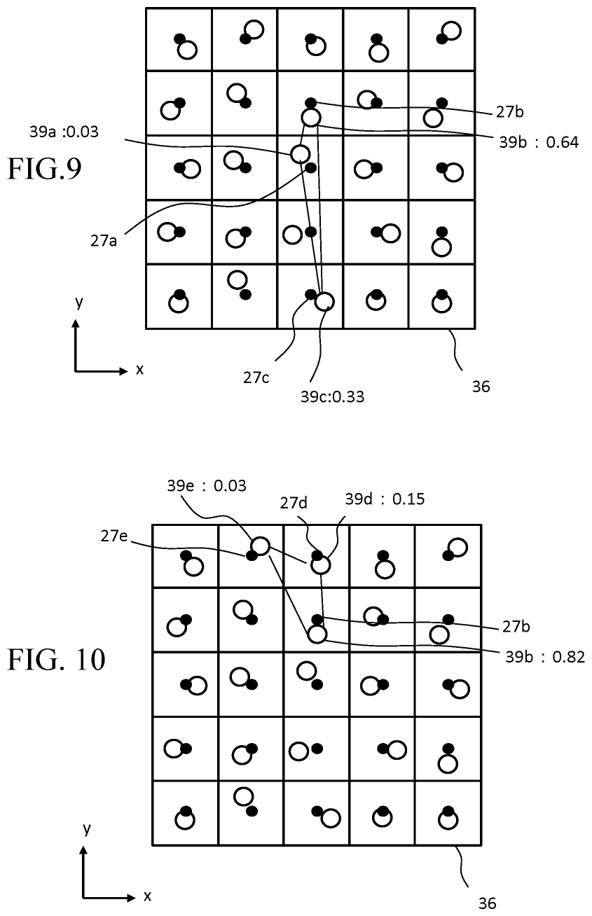

FIG. 9 is an illustration showing an example of a beam irradiation position and a dose distribution ratio in the case of correcting a position deviation according to a comparative example of the first embodiment.

FIG. 10 is an illustration showing another example of a beam irradiation position and a dose distribution ratio in the case of correcting a position deviation according to a comparative example of the first embodiment. Each of FIGS. 9 and 10 shows a region where 5×5 pixels 36 are arrayed, for example. Which beam irradiates each of the pixels 36 is determined based on the writing sequence. The actual irradiation position 39 of each beam deviates from the control grid 27, arrayed in a grid, in many cases. In the example of FIG. 9, when irradiating a control grid 27a of the center-located pixel with a desired dose, a dose to be applied to the control grid 27a is distributed among three beams surrounding the control grid 27a according to the comparative example. In the case of FIG. 9, dose distribution is performed among the beams of the irradiation positions 39a, 39b, and 39c, for example. The dose distribution ratio is calculated such that the center of gravity of the dose distribution amount is located at the control grid 27a. As a result, although the deviation amount, from the control grid 27a, of the beam of the irradiation position 39a is small, its dose distribution ratio is 0.03. The dose distribution ratio for the beam of the irradiation position 39b away from the control grid 27a is 0.64. The dose distribution ratio for the beam of the irradiation position 39c, farther than the beam of the irradiation position 39b, is 0.33. Thus, with respect to each control grid 27, the dose distribution ratio for distributing the dose to surrounding beams is similarly calculated.

FIG. 10 shows an example of the case of distributing a dose to the control grid 27b of the pixel 36 adjacent to the control grid 27a in the y direction. In the case of FIG. 10, dose distribution is performed among the beams of the irradiation positions 39b, 39d, and 39e which are surrounding the control grid 27b. Similarly to the case of the control grid 27a, the dose distribution ratio is calculated such that the center of gravity of the dose distribution amount is located at the control grid 27b. As a result, the dose distribution ratio for the beam of the irradiation position 39b closest to the control grid 27b is 0.82. The dose distribution ratio for the beam of the irradiation position 39d is 0.15. The dose distribution ratio for the beam of the irradiation position 39e is 0.03. Thus, the dose distribution ratio for the beam of the irradiation position 39b is 1.46(=0.64+0.82) based on dose distributions only with respect to the two control grids 27a and 27b. Further, there is a high possibility that the dose distribution ratio for the beam of the irradiation position 39b from the other control grids 27 will also be added. Thus, according to the comparative example, a beam is generated whose total dose distribution ratio greatly exceeds 1. A cause for this is that in spite of the deviation amount of the beam of the irradiation position 39a from the control grid 27a being small, the dose distribution ratio for the beam of the irradiation position 39a from the control grid 27a is small such as 0.03. Then, according to the first embodiment, the dose distribution ratio for the most proximate beam that irradiates each control grid 27 most closely is increased. Therefore, the steps described below are performed.

In the first proximate beam specifying step (S104), the specification unit 52 specifies, for each of a plurality of control grids 27 serving as design irradiation positions of the multiple beams 20, the most proximate beam (the first beam) that is the beam whose actual irradiation position 39 is closest to the control grid 27 concerned (target control grid 27) in the multiple beams 20.

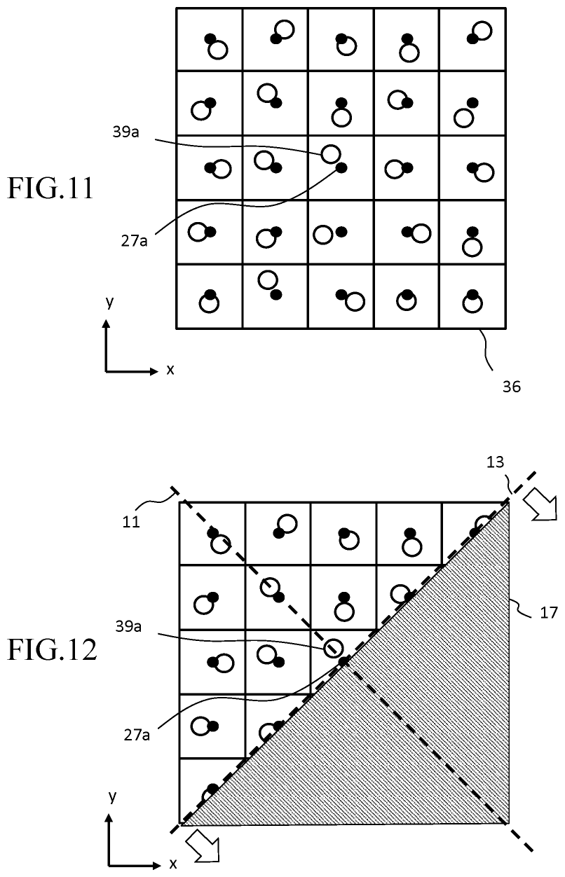

FIG. 11 is an illustration showing an example of a control grid and an actual beam irradiation position according to the first embodiment. FIG. 11 shows a region where 5×5 pixels 36 are arrayed, for example. Which beam irradiates each of the pixels 36 is determined based on the writing sequence. The actual irradiation position 39 of each beam deviates from the control grid 27, arrayed in a grid, in many cases. The case of FIG. 11 shows an example where the positional relationship between the control grid 27 and the actual beam irradiation position 39 is the same as that in FIGS. 9 and 10. It is seen from FIG. 11 that the most proximate beam closest to the control grid 27a of the center-located pixel 36 is the beam of the irradiation position 39a. Therefore, the specification unit 52 specifies the beam of the irradiation position 39a as the most proximate beam with respect to the control grid 27a. The specification unit 52 similarly specifies the most proximate beam with respect to the other control grids.

In the region restricting step (S106), the region restriction unit 54 restricts, for each control grid 27, a region (restricted region) for selecting a second selection beam (the second beam) for setting a plurality of combinations each composed of two or more beams including the most proximate beam from the multiple beams 20.

FIG. 12 is an illustration showing an example of a restricted region according to the first embodiment. In FIG. 12, a restricted region 17 is located on the opposite side to the irradiation position 39a of the most proximate beam with respect to a straight line 13 which is perpendicular to a straight line 11 connecting the control grid 27a concerned and the irradiation position 39a of the most proximate beam and passes through the control grid 27a.

In the combination setting step (S108), the setting unit 56 (combination setting unit) sets, for each control grid 27, a plurality of combinations each composed of two or more, such as three, beams including the most proximate beam in the multiple beams 20.

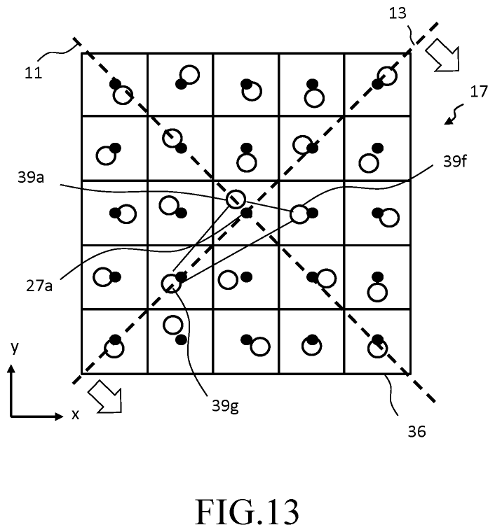

FIG. 13 is an illustration showing an example of a control grid, an actual beam irradiation position, and a combination of beams according to the first embodiment. As described above, the setting unit 56 selects, for each combination of the plurality of combinations, the second selection beam from the two or more beams in the beams within the restricted region 17. In the example of FIG. 13, the second selection beam is selected from the restricted region 17 located on the opposite side to the irradiation position 39a with respect to the straight line 13. In the case of FIG. 13, the beam of an irradiation position 39f is selected as the second selection beam (the second beam), for example. Since the second selection beam is located on the opposite side to the most proximate beam with respect to the straight line 13, the dose distribution ratio for the most proximate beam can be increased.

The setting unit 56 selects the third and subsequent selection beams in the two or more beams forming the combination. It is sufficient that the third and subsequent selection beams are located to surround the control grid 27 concerned by three or more beams forming the combination. In the case of FIG. 13, the beam of an irradiation position of 39g is selected as the third selection beam (the third beam). Thus, FIG. 13 shows the case where one combination of a plurality of combinations having been set for the control grid 27a is composed of beams of the irradiation positions 39a, 39f, and 39g. Other combinations are not shown in the figure. Although the combination composed of three beams is described here, it is sufficient to be composed of three or more beams.

In the dose distribution ratio calculating step (S110), the dose distribution ratio calculation unit 58 (distribution ratio calculation unit) calculates, for each control grid 27 and each combination of a plurality of combinations, a dose distribution ratio for each beam of two or more beams forming the combination concerned in order to distribute a dose amount, which is to be applied to the control grid 27 concerned, to the two or more beams forming the combination concerned in a manner such that the total of respective distribution dose amounts having been distributed is substantially equivalent to (e.g., equal to) the dose amount to be applied to the control grid 27 concerned. The dose distribution ratio calculation unit 58 calculates a dose distribution ratio for each beam of the two or more beams such that a deviation between the center of gravity of a dose amount obtained from each of distribution dose amounts having been distributed to the two or more beams and a corresponding control grid 27 is within an acceptable range Th. In the first embodiment, desirably, the center of gravity is completely coincident with the control grid 27, but it is not limited thereto. What is necessary is that the deviation between the center of gravity and the control grid 27 is within the acceptable range Th. For example, preferably, the deviation is within ⅕ of the pixel size. Further, more preferably, it is within 1/10 of the pixel size. When a standardized dose amount d(i) of the control grid 27 concerned is d(i)=1, dose distribution ratios d₁, d₀, and d₀ for the most proximate beam, the second selection beam, and the third selection beam can be obtained as values which satisfy the following equations (1-1) and (1-2) using a vector r being from an any desired reference position to the control grid 27 concerned and vectors r₁, r₂, and r₃ to the respective beams. i denotes an index.

$$\\ \begin{matrix}d ( i ) = {d}_{1} + {d}_{2} + {d}_{3} & ( 1 ‐ 1 )\end{matrix}$$

$$\\ \begin{matrix}d ( i ) \vec{r} - ( {d}_{1} \vec{{r}_{1}} + {d}_{2} \vec{{r}_{2}} + {d}_{3} \vec{{r}_{3}} ) \leq Th & ( 1 ‐ 2 )\end{matrix}$$

In addition to dose distribution ratios d₁, d₂, and d₃ in the case of Th=0, dose distribution ratios d₁, d₂, and d₃ in the case of Th≠0 can also be calculated. It is desirable to adopt values in the case where the dose distribution ratio d₁ for the most proximate beam is as large as possible.

In the current density correcting step (S112), the current density correction unit 60 (weighting processing unit) calculates, for each control grid 27 and each combination of a plurality of combinations, a weighted dose distribution ratio by performing weighting on a dose distribution ratio for two or more beams by using a current density correction value for correcting a deviation of current density.

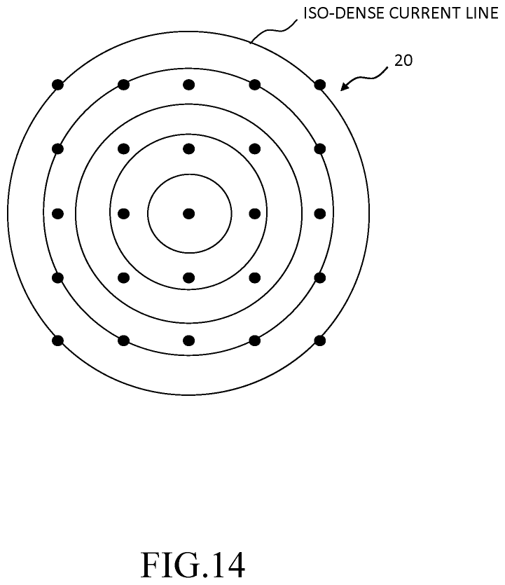

FIG. 14 is an illustration showing an example of a current density distribution according to the first embodiment. FIG. 14 shows the case where the 5×5 multiple beams 20 are used. As shown in the distribution of FIG. 14, generally, the current density is highest in the center beam and decreases toward the outer circumference. Therefore, the incident dose amount differs depending on the case being irradiated with the center beam or with the outer circumferential beam even during the same irradiation time. Then, the current density correction unit 60 calculates a dose distribution ratio weighted by a current density correction value which corrects deviation of the current density of a beam concerned. A weighted dose distribution ratio di′ can be defined by the following equation (2). Specifically, the weighted dose distribution ratio di′ can be acquired by multiplying a dose distribution ratio di for the i-th selection beam by a ratio obtained by dividing an ideal current density J by an actual current density J(i) of the i-th selection beam. Thereby, a weighted dose distribution ratio di′ for the i-th selection beam can be calculated. A ratio (J/J (i)) obtained by dividing an ideal current density J by an actual current density J(i) of the i-th selection beam is an example of the current density correction value.

$$\\ \begin{matrix}{d}_{i}^{{}_{} ′} = {d}_{i} \frac{J}{J ( i )} & ( 2 )\end{matrix}$$

In the case of performing n-times multiple writing, beams to be distributed to respective control grids 227 are different from each other. When uniformly dividing, in each pass, an irradiation time to be used for irradiation of each control grid 27, the irradiation time of each pass can be weighted by a ratio obtained by dividing a total ideal current density n·J, being a total of ideal current densities to be used n times, by a total of current densities, each being J(i), of respective beams for each pass. By contrast, at each pass, two or more beams for which dose distribution is performed from each control grid 27 are different from each other. Therefore, the irradiation position of the second selection beam and/or the third selection beam of each pass may be possibly completely different from that of the other passes. Meanwhile, the most proximate beam is applied to the vicinity of the control grid 27 concerned. Then, for each control grid 27, by using a current density J(i) of the most proximate beam of each pass, the dose distribution ratio di for each of two or more beams of each pass is weighted by a ratio obtained by dividing a total ideal current density n·J, being a total of ideal current densities to be used n times, by a total of current densities, each being J(i), of respective most proximate beams for each pass. The weighted dose distribution ratio di′ can be defined by the following equation (3). A ratio obtained by dividing a total ideal current density n·J, being a total of ideal current densities to be used n times, by a total of current densities, each being J(i), of respective most proximate beams for each pass is another example of the current density correction value.

$$\\ \begin{matrix}{d}_{i}^{{}_{} ′} = {d}_{i} \frac{nJ}{{\sum }_{i}^{n} J ( i )} & ( 3 )\end{matrix}$$

Here, if the standardized ideal current density J is 1, the current density of the most proximate beam of each pass of four-times multiple writing is individually assumed to be 1.0, 0.9, 0.95 and 0.85, for example. The current density correction value based on the equation (2) is, for each pass, (1.0/1.0), (1.0/0.9), (1.0/0.95), and (1.0/0.85). Therefore, the maximum value in these is 1.18 (=1.0/0.85). In contrast, in calculation for the current density correction value based on the equation (3), the total value of actual current densities of four passes is 3.7(=1.0+0.9+0.95+0.85). The total of ideal current densities of four passes, n·J, is 4 (=4×1.0). Accordingly, the current density correction value of each pass is 1.08 (=4/3.7), and thus, it is possible to make it smaller than the one based on the equation (2).

In the combination selecting step (S114), the combination selection unit 62 selects, for each control grid 27, a combination in which the dose distribution ratio for the most proximate beam is larger than that for one or more beams remailing except for the most proximate beam in two or more beams forming the combination concerned. If there are two or more combinations in each of which the dose distribution ratio for the most proximate beam is larger than that for one or more beams except for the most proximate beam in two or more beams forming the combination concerned, it is preferable to select a combination in which the dose distribution ratio for the most proximate beam is largest.

If the current density correcting step (S112) is omitted, the dose distribution ratio before being weighted by a current density correction value is used as the target dose distribution ratio in the combination selecting step (S114). When the current density correcting step (S112) is executed, the combination selection unit 62 selects a combination in which the weighted dose distribution ratio for the most proximate beam is larger than that for one or more beams except for the most proximate beam in two or more beams forming the combination concerned.

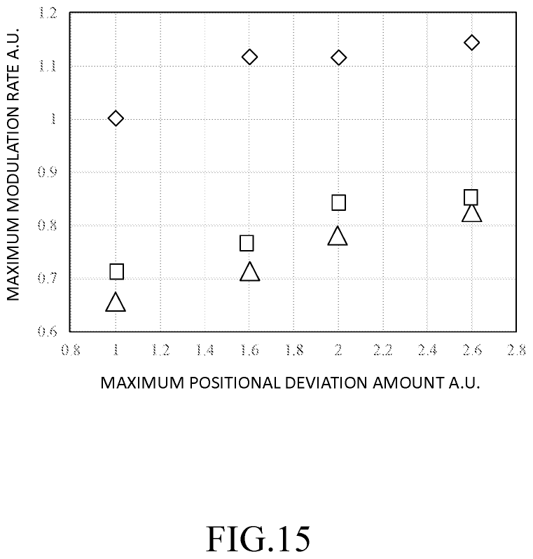

FIG. 15 is an illustration showing an example of a result of simulation on a relationship between the maximum modulation rate and the maximum positional deviation amount associated with positional deviation correction according to the first embodiment. In FIG. 15, the ordinate axis represents the maximum modulation rate, and the abscissa axis represents the maximum positional deviation amount of the multiple beams 20. The maximum modulation rate is defined by the maximum value in the total dose distribution ratios obtained by totaling the dose distribution rates distributed by each control grid 27 for each beam. Data denoted by ⋄ shows the case where no consideration is given to make the dose distribution ratio for the most proximate beam larger than that of the other beams. From the example of FIG. 15, it turns out that the maximum modulation rate is one or more in any case when no consideration is given to make the dose distribution ratio for the most proximate beam larger. Further, it also turns out that, as the positional deviation amount increases, the maximum modulation rate also increases. In contrast, according to the first embodiment, it is possible to reduce the maximum modulation rate (data denoted by □) by selecting a combination such that the dose distribution ratio for the most proximate beam is larger than that for the other beams. In that case, also similarly, there is the tendency that the maximum modulation rate increases as the positional deviation amount increases. Furthermore, it is possible to further reduce the maximum modulation rate (data denoted by A) by selecting a combination after performing weighting on the dose distribution ratio by a current density correction value. The current density correction value in the example of FIG. 15 is based on the ratio of the equation (3).

Next, the case of executing the repetitive operation processing step (S118) is descried below.

In the repetitive operation processing step (S118), while changing, for each control grid, a selected combination, each time, the repetitive operation processing unit 64 calculates a total dose distribution ratio totaled for each beam design irradiation position in the whole beam array. Specifically, it operates as follows:

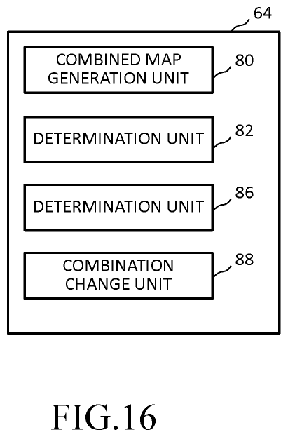

FIG. 16 is a block diagram showing an example of the internal configuration of a repetitive operation processing unit according to the first embodiment. In FIG. 16, in the repetitive operation processing unit 64, there are arranged a combined map generation unit 80, a determination unit 82, a determination unit 86, and a combination change unit 88. Each of the “ . . . units” such as the combined map generation unit 80, the determination unit 82, the determination unit 86, and the combination change unit 88 includes processing circuitry. The processing circuitry includes, for example, an electric circuit, computer, processor, circuit board, quantum circuit, or semiconductor device. Each “ . . . unit” may use common processing circuitry (the same processing circuitry), or different processing circuitry (separate processing circuitry). Information input/output to/from the combined map generation unit 80, the determination unit 82, the determination unit 86, and the combination change unit 88, and information being operated are stored in the memory 112 each time.

In the combined map generating step (S120), the combined map generation unit 80 (total calculation unit) calculates a total dose distribution ratio by totaling (combining), for each beam design irradiation position, dose distribution ratios for two or more beams forming a combination selected for each control grid 27 in the whole beam array of the multiple beams 20. Then, a combined map is generated whose element is a total dose distribution ratio of each beam design irradiation position. Preferably, the combined map has a beam array being the same as that of the multiple beams 20. There is a case where dose distribution is performed for one beam from a plurality of control grids 27. Therefore, ratios of dose distributions from a plurality of control grids 27 are combined per beam design irradiation position. Here, it is sufficient to simply calculate a total value.

In the determining step (S122), the determination unit 82 determines whether the maximum value (maximum modulation amount) of the total dose distribution ratio of each beam design irradiation position in the k-th combination selected for each control grid 27 is smaller than that in the (k−1) th and pervious combinations each selected for each control grid 27. Since it is impossible for the initial time combination to perform comparison with the maximum value of the total dose distribution ratio of the last and previous time combinations, the determination should just be “not smaller”. Then, at the second and subsequent time combinations, since the maximum modulation amount of the previous time exists, determination should be made each time to determine “larger or smaller”. When the maximum modulation amount becomes smaller, it proceeds to the combination updating step (S124). When the maximum modulation amount does not become smaller, it proceeds to the combination changing step (S125). At this process, temporarily, the total dose distribution ratio may be updated. In that case, the updating is performed for only the portion associated with the control grid 27 concerned.

In the combination updating step (S124), when the maximum value of the total dose distribution ratio of each beam design irradiation position of the k-th combination (k being an inter of 2 or more) in the whole beam array is smaller than that of the (k−1) th and pervious combinations in the whole beam array, the combination selection unit 62 reselects a combination for each control grid 27 which serves as a basis of the total dose distribution ratio of each beam design irradiation position of the k-th combination in the whole of beam array. In other words, the combination for each control grid 27, which is currently selected, is updated (reselected). Along with this, the total dose distribution ratio is updated. This updating is performed for only the portion associated with the control grid 27 whose combination has been updated.

In the combination changing step (S125), the combination change unit 88 changes a combination selected for each control grid 27. The most proximate beam is specified for each control grid 27. The second selection beam is restricted to be a beam whose irradiation position 39 exists in the restricted region 17. Based on these conditions, changing combination to another is executed. If there are, for each control grid 27, two or more combinations in each of which the dose distribution ratio for the most proximate beam is larger than that of one or more beams except for the most proximate beam in two or more beams forming the combination concerned, the combination changing may also preferably be performed in these two or more combinations. Then, it returns to the combined map generating step (S120), and steps from the combined map generating step (S120) to the combination changing step (S125) are repeated until reaching specified number of times in the next determining step (S126). At the combined map generating step (S120) in the repeating process, it is not limited to the case of recalculating the total dose distribution ratio of each beam design irradiation position in the whole beam array, and only the total dose distribution ratio of the irradiation position in the target combination having been changed for the control grid may be calculated.

In the determining step (S126), the determination unit 86 determines whether the number of times k of the repetitive operation of updating the combination has reached the number of times m that has been preset. When the number of times k of the repetitive operation of updating the combination has reached the preset number of times m, the combination for each control grid 27 currently selected is maintained and the repetitive operation processing is finished. When the number of times k of the repetitive operation of updating the combination has not reached the preset number of times m, it proceeds to the combination changing step (S125). Even if the number of times k of the repetitive operation of updating the combination has not reached the number of times m, when the difference between the maximum value of the k-th operation and that of the (k−1) th operation is smaller than a preset value, it is also preferable to finish the repetitive operation processing. Further, as a result of performing the repetitive operation processing, even if no combination has been updated, when the number of times of the repetitive operation processing at the control grid concerned has reached the preset number of times q, with respect to each control grid, the repetitive operation processing at the control grid concerned may also be finished.

Then, it returns to the combined map generating step (S120), and each step from the combined map generating step (S120) to the combination changing step (S125) is repeated until the number of times k of the repetitive operation processing has reached the preset number of times m.

While changing the combination selected for each control grid 27, each time, the combined map generation unit 80 calculates a total dose distribution ratio totaled for each beam design irradiation position in the whole beam array. As the dose distribution ratio for each of two or more beams forming each combination which has been changed, the calculation result already obtained in the dose distribution ratio calculating step (S110) can be used.

The total dose distribution ratio of each beam design irradiation position changes by changing the combination for each control grid 27. Consequently, the maximum modulation rate after performing combination changes. Therefore, the maximum modulation rate can further be reduced by performing the repetitive operation processing (iteration).

The modulation rate of each of two or more beams which form a combination selected for each control grid 27 is stored, as positional deviation correction data, in the storage device 144. It is sufficient for the positional deviation correction data to be generated with respect to one quadrangle unit region 35 on the surface of the target object corresponding to the irradiation region 34.

In the dose amount calculating step (S130), the dose map generation unit 68 (dose amount calculation unit) calculates, for each writing pattern, a dose amount of each pixel 36 on the target object 101 corresponding to the writing pattern concerned. Specifically, it operates as follows: First, the rasterization unit 66 reads writing data from the storage device 140, and calculates, for each pixel 36, a pattern area density ρ′ in the pixel 36 concerned. This processing is performed for each stripe region 32, for example.

Next, the dose map generation unit 68, first, virtually divides the writing region (here, for example, stripe region 32) into a plurality of proximity mesh regions (mesh regions for proximity effect correction calculation) by a predetermined size. The size of the proximity mesh region is preferably about 1/10 of the influence range of the proximity effect, such as about 1 μm. The dose map generation unit 68 reads writing data from the storage device 140, and calculates, for each proximity mesh region, a pattern area density ρ of a pattern arranged in the proximity mesh region concerned.

Next, the dose map generation unit 68 calculates, for each proximity mesh region, a proximity effect correction irradiation coefficient Dp (x) (correction dose) for correcting a proximity effect. An unknown proximity effect correction irradiation coefficient Dp (x) can be defined by a threshold value model for proximity-effect correction, which is the same as the one used in a conventional method, where a backscatter coefficient η, a dose threshold value Dth of a threshold value model, a pattern area density ρ, and a distribution function g (x) are used.

Next, the dose map generation unit 68 calculates, for each pixel 36, an incident dose D (x) (amount of dose) with which the pixel 36 concerned is irradiated. The incident dose D (x) can be calculated, for example, by multiplying a preset base dose Dbase by a proximity effect correction irradiation coefficient Dp and a pattern area density ρ′. The base dose Dbase can be defined by Dth/(½+η), for example. Thereby, it is possible to obtain an originally desired incident dose D (x), for which a proximity effect has been corrected, based on layout of a plurality of figure patterns defined by the writing data.

The dose map generation unit 68 generates a dose map defining the incident dose D (x) for each pixel 36 per stripe. Such incident dose D (x) for each pixel 36 serves as a design incident dose D (x) with which the control grid 27 of the pixel 36 concerned is to be irradiated. In other words, the dose map generation unit 68 generates a dose map defining an incident dose D (x) for each control grid 27 per stripe. The generated dose map is stored in the storage device 144, for example.

In the dose correcting step (S134), the dose correction unit 70 reads, for each writing pattern, positional deviation correction data from the storage device 144, and corrects a dose amount by applying the positional deviation correction data to an individual dose amount of each pixel corresponding to the writing pattern concerned. Specifically, the dose correction unit 70 distributes, for each control grid 27, an incident dose D (x) which is to be applied to a target control grid 27 concerned, to pixels being design irradiation positions of two or more beams, forming a selected combination, based on dose distribution ratios of distribution to the design irradiation positions of two or more beams. Then, dose amounts distributed to respective pixels being design irradiation positions are added. In other words, the dose correction unit 70 corrects a dose amount of the pixel concerned by to which adding a dose amount having been distributed to each pixel, and outputs a corrected correction dose amount. The dose amount to be added to the pixel concerned is equivalent to a dose remained after distribution to the other pixels if the distribution to the other pixels is to be performed.

In the irradiation time calculation step (S140), the irradiation time calculation unit 72 calculates an irradiation time t corresponding to the dose amount of each pixel for which beam position deviation has been corrected. The irradiation time t can be obtained by dividing the dose D by a current density J. The irradiation time t of each pixel 36 (control grid 27) is calculated as a value within the maximum irradiation time Ttr which is the maximum for irradiation by one shot of the multiple beams 20. The irradiation time t of each pixel 36 (control grid 27) is converted into gray level data of 0 to 1023 gray levels defining the maximum irradiation time Ttr to be 1023 gray levels (10 bits), for example. The gray-level irradiation time data is stored in the storage device 142.

In the writing step (S142), first, the writing control unit 74 rearranges irradiation time data in the order of shot in accordance with the writing sequence. Then, the irradiation time data is transmitted to the deflection control circuit 130 in the order of shot. The deflection control circuit 130 outputs a blanking control signal to the blanking aperture array mechanism 204 in the order of shot, and deflection control signals to the DAC amplifier units 132 and 134 in the order of shot. The writing mechanism 150 writes a pattern on the target object 101 by using the multiple beams 20 having been distributed to two or more beams forming a combination composed of selected doses to be applied to each control grid 27. In other words, a pattern is written on the target object 101 by using the multiple beams 20 of a corrected dose amount having been corrected by a dose amount addition performed in the dose correcting step (S134).

As described above, according to the first embodiment, it is possible in multiple beam writing to suppress an increase in a dose modulation rate when correcting a position deviation of each beam by dose modulation. Therefore, an increase in the maximum irradiation time can be suppressed, and thus, that in writing time can also be suppressed.

Embodiments have been explained referring to specific examples described above. However, the present invention is not limited to these specific examples. The above examples describe the case where each of the multiple beams 20 individually controls, for each beam, the irradiation time within the maximum irradiation time Ttr for one shot. However, it is not limited thereto. For example, the maximum irradiation time Ttr for one shot is divided into a plurality of sub-shots each having a different irradiation time. Then, for each beam, a combination of sub-shots is selected from the plurality of sub-shots in order that the combination may become the irradiation time for one shot. It is also preferable to control, for each beam, the irradiation time for one shot by continuously applying, to the same pixel, irradiation of a combination of sub-shots selected for the same beam.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Further, any multi-charged particle beam writing apparatus and multi-charged particle beam writing method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-charged particle beam writing apparatus comprising:
a beam forming mechanism configured to form multiple charged particle beams;
a specification circuit configured to specify, for each control grid of a plurality of control grids serving as beam design irradiation positions of the multiple charged particle beams, a first beam whose actual irradiation position is closest to a control grid of a beam concerned in the multiple charged particle beams;
a combination setting circuit configured to set, for the each control grid, a plurality of combinations each composed of at least two beams, including the first beam, in the multiple charged particle beams;
a distribution ratio calculation circuit configured to calculate, for the each control grid and each combination of the plurality of combinations, a dose distribution ratio for each beam of the at least two beams forming a combination concerned in order to distribute a dose amount, which is to be applied to a control grid concerned, to the at least two beams forming the combination concerned such that a total of distribution dose amounts having been distributed to the at least two beams forming the combination concerned is substantially equivalent to the dose amount to be applied to the control grid concerned;
a combination selection circuit configured to select, for the each control grid, a combination in which a dose distribution ratio for the first beam is larger than a dose distribution ratio for at least one beam remaining in the at least two beams forming the combination concerned;
a dose correction circuit configured to correct a dose amount of an irradiation position concerned by to which adding a dose amount having been distributed to each beam design irradiation position based on dose distribution ratios for the at least two beams forming the combination selected for the each control grid in a whole beam array of the multiple charged particle beams, and configured to output a corrected dose amount; and
a writing mechanism configured to write a pattern on a target object by using the multiple charged particle beams of the corrected dose amount.

2. The apparatus according to claim 1, wherein
the combination setting circuit selects, for the each combination of the plurality of combinations, a second beam in the at least two beams in beams within a restricted region.

3. The apparatus according to claim 2, wherein
the restricted region is located on an opposite side to an irradiation position of the first beam with respect to a straight line which is perpendicular to a straight line connecting a control grid concerned of the first beam and the irradiation position of the first beam and passes through the control grid concerned of the first beam.

4. The apparatus according to claim 1, wherein
the distribution ratio calculation circuit calculates the dose distribution ratio for the each beam of the at least two beams such that a deviation between a center of gravity of a dose amount obtained from each of the distribution dose amounts having been distributed to the at least two beams and a corresponding control grid is within an acceptable range.

5. The apparatus according to claim 1 further comprising:
a weighting processing circuit configured to calculate, for the each control grid and the each combination of the plurality of combinations, a weighted dose distribution ratio by performing weighting on the dose distribution ratio for the at least two beams by using a current density correction value for correcting a deviation of current density.

6. The apparatus according to claim 1 further comprising:
a total calculation circuit configured to calculate a total dose distribution ratio by totaling, for the each beam design irradiation position, the dose distribution ratios for the at least two beams forming the combination selected for the each control grid in the whole beam array of the multiple charged particle beams, wherein
the total calculation circuit calculates, while changing the combination selected for the each control grid, each time, the total dose distribution ratio totaled for the each beam design irradiation position in the whole beam array, and the combination selection circuit reselects a combination for each control grid, which serves as a basis of the total dose distribution ratio of each beam design irradiation position of a k-th combination (k being an integer of at least 2) in the whole beam array in a case where a maximum value of the total dose distribution ratio of the each beam design irradiation position of the k-th combination in the whole beam array is smaller than a maximum value of the total dose distribution ratio of each beam design irradiation position of a (k−1) th and pervious combinations in the whole beam array.

7. A multi-charged particle beam writing method comprising:
forming multiple charged particle beams;
specifying, for each control grid of a plurality of control grids serving as beam design irradiation positions of the multiple charged particle beams, a first beam whose actual irradiation position is closest to a control grid of a beam concerned in the multiple charged particle beams;
setting, for the each control grid, a plurality of combinations each composed of at least two beams, including the first beam, in the multiple charged particle beams;
calculating, for the each control grid and each combination of the plurality of combinations, a dose distribution ratio for each beam of the at least two beams forming a combination concerned in order to distribute a dose amount, which is to be applied to a control grid concerned, to the at least two beams forming the combination concerned such that a total of distribution dose amounts having been distributed to the at least two beams forming the combination concerned is substantially equivalent to the dose amount to be applied to the control grid concerned;
selecting, for the each control grid, a combination in which a dose distribution ratio for the first beam is larger than a dose distribution ratio for at least one beam remaining in the at least two beams forming the combination concerned;
correcting a dose amount of an irradiation position concerned by to which adding a dose amount having been distributed to each beam design irradiation position based on dose distribution ratios for the at least two beams forming the combination selected for the each control grid in a whole beam array of the multiple charged particle beams, and outputting a corrected dose amount; and
writing a pattern on a target object by using the multiple charged particle beams of the corrected dose amount.

8. The method according to claim 7, wherein,
in the selecting the combination, a second beam in the at least two beams is selected in beams within a restricted region for the each combination of the plurality of combinations.

9. The method according to claim 8, wherein
the restricted region is located on an opposite side to an irradiation position of the first beam with respect to a straight line which is perpendicular to a straight line connecting a control grid concerned of the first beam and the irradiation position of the first beam and passes through the control grid concerned of the first beam.
